(19) United States
(12) Patent Application Publication
(10) Pub. No.: US 2024/0429027 A1
(43) Pub. Date: Dec. 26, 2024

(54) PLASMA PROCESSING APPARATUS

(71) Applicant: Tokyo Electron Limited, Tokyo (JP)

(72) Inventors: Noriyuki SAKAYA, Miyagi (JP); Sho SAITOH, Miyagi (JP); Yoshimitsu KON, Miyagi (JP)

(73) Assignee: Tokyo Electron Limited, Tokyo (JP)

(21) Appl. No.: 18/830,771

(22) Filed: Sep. 11, 2024

Related U.S. Application Data
(63) Continuation of application No. PCT/JP2023/008617, filed on Mar. 7, 2023.

(30) Foreign Application Priority Data
Mar. 31, 2022 (JP) 2022-060937

(51) Int. Cl. H01J 37/32

(52) U.S. Cl. CPC H01J 37/32174; H01J 37/32568; H01J 2237/334

(57) ABSTRACT

A plasma processing apparatus includes a plasma processing chamber; a substrate support disposed within the plasma processing chamber and including a lower electrode; an upper electrode disposed above the substrate support; and an RF power supply configured to supply an RF signal to the upper electrode or the lower electrode, the RF signal having a first power level during a first sub-period in a repetition period and a second power level during a second sub-period in the repetition period; and a DC power supply configured to supply a DC signal to the lower electrode. The DC signal has an OFF-state during a delay period in the first sub-period, has a sequence of a plurality of DC pulses during the first sub-period excluding the delay period, and has an OFF-state during the second sub-period, the delay period being within a range of 2% to 7% of the repetition period.

### CROSS-REFERENCE TO RELATED APPLICATIONS

This application is a continuation application of International Patent Application No. PCT/JP2023/008617, filed on Mar. 7, 2023, which claims priority to Japanese Patent Application No. 2022-060937, filed on Mar. 31, 2022, with the Japan Patent Office, all of which are incorporated herein their entireties by reference.

### TECHNICAL FIELD

The present disclosure relates to a plasma processing apparatus.

### BACKGROUND

In Japanese Patent Application Laid-Open No. 2020-077862, a technique is disclosed in which radio-frequency power is supplied, and then, a negative direct current (DC) voltage is applied to a lower electrode of a substrate support, to etch a substrate by positive ions from a plasma. Subsequently, the supply of radio frequency power and the application of the negative DC voltage are stopped, and then, a positive DC voltage is applied to the lower electrode. As a result, negative ions are supplied to the substrate, and the amount of electrostatic charges on the substrate is reduced by the negative ions, thereby improving etching efficiency.

### SUMMARY

According to an aspect of the present disclosure, a plasma processing apparatus is provided. The plasma processing apparatus includes a plasma processing chamber, a substrate support disposed within the plasma processing chamber and including a lower electrode; an upper electrode disposed above the substrate support; and a radio-frequency (RF) power supply configured to supply an RF signal to the upper electrode or the lower electrode, the RF signal having a first power level during a first sub-period in a repetition period and a second power level during a second sub-period in the repetition period; and a direct current (DC) power supply configured to supply a DC signal to the lower electrode. The DC signal has an OFF-state during a delay period in the first sub-period, has a sequence of a plurality of DC pulses during the first sub-period excluding the delay period, and has an OFF-state during the second sub-period, the delay period being within a range of 2% to 7% of the repetition period.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram illustrating an example of a plasma processing system according to an embodiment of the present disclosure.

FIGS. 2A to 2D are a time chart illustrating RF power and a DC pulse voltage according to the embodiment.

FIGS. 3A and 3B are diagrams illustrating an increase in DC pulse voltage according to the embodiment and Comparative Example.

FIGS. 4A and 4B are diagrams illustrating a relationship between an offset period, and electron density and RF power according to the embodiment.

FIG. 5 is a diagram illustrating RF power and mask remains during an offset period according to the embodiment.

FIG. 6 is a diagram illustrating another example of a plasma processing system according to an embodiment of the present disclosure.

### DETAILED DESCRIPTION

In the following detailed description, reference is made to the accompanying drawings, which form a part thereof. The illustrative embodiments described in the detailed description, drawings, and claims are not meant to be limiting. Other embodiments may be used, and other changes may be made without departing from the spirit or scope of the subject matter presented here.

Hereinafter, embodiments for carrying out the present disclosure will be described with reference to the accompanying drawings. In each drawing, the same components are designated by the same reference numerals, and redundant description thereof may be omitted.

In this specification, parallel, right angle, orthogonal, horizontal, vertical, up and down, and left and right directions are allowed to deviate to the extent that the effect of the embodiments is not impaired. The shape of corners is not limited to right angles and may be arcuate. The terms parallel, right angle, orthogonal, horizontal, vertical, circular, and coincident may include substantially parallel, substantially right angle, substantially orthogonal, substantially horizontal, substantially vertical, substantially circular, and substantially coincident, respectively.

### [Plasma Processing System]

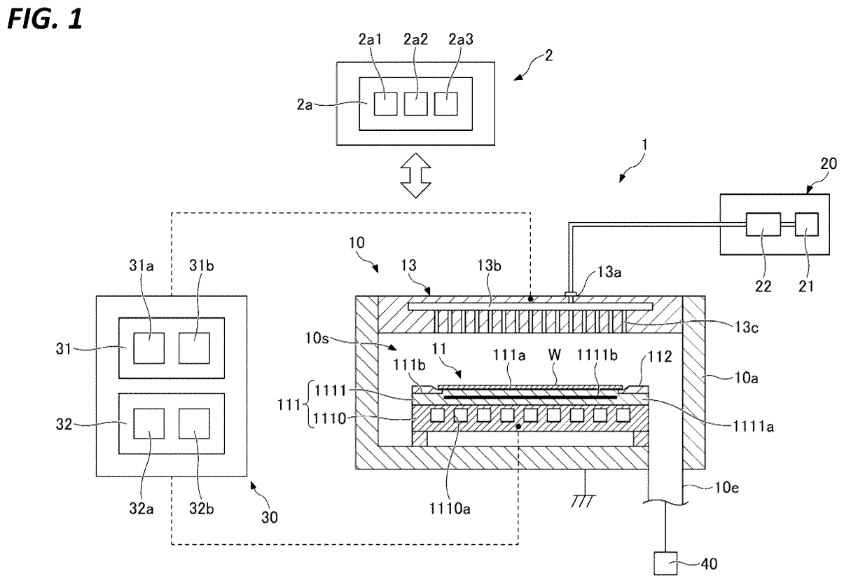

Hereinafter, an example of a configuration of a plasma processing system will be described. FIG. 1 illustrates an example of a configuration of a capacitively-coupled plasma processing apparatus.

The plasma processing system includes a capacitively-coupled plasma processing apparatus 1 and a control unit 2. The capacitively-coupled plasma processing apparatus 1 includes a plasma processing chamber 10, a gas supply unit 20, a power supply 30, and an exhaust system 40. The plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed within the plasma processing chamber 10. The shower head 13 is disposed above the substrate support 11. In an embodiment, the shower head 13 constitutes at least a portion of a ceiling of the plasma processing chamber 10. The plasma processing chamber 10 includes a plasma processing space 10s defined by the shower head 13, sidewalls 10a of the plasma processing chamber 10, and the substrate support 11. The plasma processing chamber 10 includes at least one gas supply inlet for supplying at least one processing gas to the plasma processing space 10s and at least one gas outlet for discharging the gas from the plasma processing space. The plasma processing chamber 10 is grounded. The shower head 13 and the substrate support 11 are electrically isolated from a case of the plasma processing chamber 10.

The substrate support 11 includes a body portion 111 and a ring assembly 112. The body portion 111 includes a central region 111a for supporting a substrate W and an annular region 111b for supporting the ring assembly 112. A wafer is an example of the substrate W. The annular region 111b of the body portion 111 surrounds the central region 111a of the body portion 111 as viewed in plan view. The substrate W is disposed on the central region 111a of the body portion 111, and the ring assembly 112 is disposed on the annular region 111b of the body portion 111 to surround the substrate W on the central region 111a of the body portion 111. Thus, the central region 111a may also be referred to as a substrate support surface for supporting the substrate W, and the annular region 111b may also be referred to as a ring support surface for supporting the ring assembly 112.

In an embodiment, the body portion 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed within the ceramic member 1111a. The ceramic member 1111a includes a central region 111a. In the embodiment, the ceramic member 1111a also includes the annular region 111b. Further, another member surrounding the electrostatic chuck 1111, such as an annular electrostatic chuck or an annular insulating member, may also have the annular region 111b. In this case, the ring assembly 112 may be disposed on the annular electrostatic chuck or annular insulating member, or may be disposed on both the electrostatic chuck 1111 and the annular insulating member. At least one RF/DC electrode coupled to a radio frequency (RF) power supply 31 and/or a direct current (DC) power supply 32 to be described later may be disposed within the ceramic member 1111a. In this case, the at least one RF/DC electrode functions as a lower electrode. When a bias RF signal and/or a DC signal to be described later is supplied to the at least one RF/DC electrode, the RF/DC electrode is also called a lower electrode. The conductive member of the base 1110 and the at least one RF/DC electrode may function as a plurality of lower electrodes. In addition, the electrostatic electrode 1111b may function as a lower electrode. Therefore, the substrate support 11 includes at least one lower electrode.

The ring assembly 112 includes one or more annular members. In the embodiment, the one or more annular members include one or more edge rings and at least one cover ring. The edge rings are formed of a conductive material or an insulating material, and the cover ring is formed of an insulating material.

The substrate support 11 may include a temperature control module configured to regulate at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In the embodiment, the flow path 1110a is formed within the base 1110, and one or more heaters are disposed within the ceramic member 1111a of the electrostatic chuck 1111. The substrate support 11 may include a heat transfer gas supply configured to supply a heat transfer gas to a gap between a back surface of the substrate W and the central region 111a.

The shower head 13 is configured to introduce at least one processing gas from the gas supply unit 20 into the plasma processing space 10s. The shower head 13 includes at least one gas supply inlet 13a, at least one gas diffusion chamber 13b, and a plurality of gas introduction inlets 13c. A processing gas supplied to the gas supply inlet 13a, passes through the gas diffusion chamber 13b and is introduced into the plasma processing space 10s from the plurality of gas introduction inlets 13c. The shower head 13 includes at least one upper electrode. The gas introduction unit may include one or more side gas injectors (SGI) attached to one or more openings formed in the sidewall 10a, in addition to the shower head 13.

The gas supply unit 20 may include at least one gas source 21 and at least one flow controller 22. In the embodiment, the gas supply unit 20 is configured to supply at least one processing gas to the shower head 13 from the gas source 21 corresponding to each processing gas through the flow controller 22 corresponding to each processing gas. Each flow controller 22 may include, for example, a mass flow controller or a pressure-controlled flow controller. In addition, the gas supply unit 20 may include at least one flow modulation device for modulating or pulsing a flow of at least one processing gas.

The power supply 30 includes an RF power supply 31 coupled to the plasma processing chamber 10 through at least one impedance matching circuit. The RF power supply 31 is configured to supply at least one RF signal (RF power) to at least one lower electrode and/or at least one upper electrode. Accordingly, a plasma is formed from at least one processing gas supplied to the plasma processing space 10s. Therefore, the RF power supply 31 may function as at least a portion of a plasma generating unit configured to generate a plasma from one or more processing gases in the plasma processing chamber 10. By supplying a bias RF signal to the at least one lower electrode, a bias potential is generated at the substrate W, so that ion components in the formed plasma may be introduced to the substrate W.

In the embodiment, the RF power supply 31 includes a first RF generating unit 31a and a second RF generating unit 31b. The first RF generating unit 31a is coupled to the at least one lower electrode and/or at least one upper electrode through at least one impedance matching circuit and is configured to generate a source RF signal (source RF power) for plasma generation. In the embodiment, the source RF signal has a frequency in a range of 10 MHz to 150 MHz. In the embodiment, the first RF generating unit 31a may be configured to generate a plurality of source RF signals having different frequencies. The generated one or more source RF signals are supplied to the at least one lower electrode and/or at least one upper electrode.

The second RF generating unit 31b is coupled to the at least one lower electrode through at least one impedance matching circuit and is configured to generate a bias RF signal (bias RF power). A frequency of the bias RF signal may be the same as or different from a frequency of the source RF signal. In the embodiment, the bias RF signal has a frequency lower than the frequency of the source RF signal. In the embodiment, the bias RF signal has a frequency within a range of 100 kHz to 60 MHz. In the embodiment, the second RF generating unit 31b may be configured to generate a plurality of bias RF signals having different frequencies. The generated one or more bias RF signals are supplied to the at least one lower electrode. In various embodiments, at least one of the source RF signal and the bias RF signal may be pulsed.

The power supply 30 may include a DC power supply 32 coupled to the plasma processing chamber 10. The DC power supply 32 includes a first DC generating unit 32a and a second DC generating unit 32b. In the embodiment, the first DC generating unit 32a is connected to the at least one lower electrode and configured to generate a first DC signal. The generated first DC signal (first bias DC signal) is applied to the at least one lower electrode. In the embodiment, the second DC generating unit 32b is connected to at least one upper electrode and configured to generate a second DC signal. The generated second DC signal is applied to the at least one upper electrode.

In various embodiments, at least one of the first DC signal and the second DC signal may be pulsed. In this case, a sequence of voltage pulses is applied to the at least one lower electrode and/or at least one upper electrode. The voltage pulses may have a pulse waveform of a rectangle, a trapezoid, a triangle, or a combination thereof. In the embodiment, a waveform generating unit for generating a sequence of voltage pulses from the DC signal is connected between the first DC generating unit 32a and the at least one lower electrode. Therefore, the first DC generating unit 32a and the waveform generating unit constitute a voltage pulse generating unit. When the second DC generating unit 32b and the waveform generating unit constitute the voltage pulse generating unit, the voltage pulse generating unit is connected to the at least one upper electrode. The voltage pulse may have a positive polarity or a negative polarity. The sequence of voltage pulses may include one or more positive voltage pulses and one or more negative voltage pulses within one cycle. The first DC generating unit 32a and the second DC generating unit 32b may be installed, in addition to the RF power supply 31. Alternatively, the first DC generating unit 32a may be installed, instead of the second RF generating unit 31b.

The exhaust system 40 may be connected to a gas outlet 10e, for example, provided at a bottom of the plasma processing chamber 10. The exhaust system 40 may include a pressure regulating valve and a vacuum pump. By the pressure regulating valve, a pressure in the plasma processing space 10s is regulated. The vacuum pump may include a turbomolecular pump, a dry pump, or a combination thereof.

The control unit 2 processes computer-executable instructions that cause the plasma processing apparatus 1 to execute various processes described herein. The control unit 2 may be configured to control each element of the plasma processing apparatus 1 to execute various processes described herein. In the embodiment, a portion or whole of the control unit 2 may be included in the plasma processing apparatus 1. The control unit 2 may include a processing unit 2a1, a storage unit 2a2 and a communication interface 2a3. The control unit 2 is implemented, for example, by a computer 2a. The processing unit 2al may be configured to perform various control operations by reading a program from the storage unit 2a2 and executing the read program. The program may be stored in the storage unit 2a2 in advance, or may be acquired through a medium, when necessary. The acquired program is stored in the storage unit 2a2 and is read from the storage unit 2a2 by the processing unit 2al to be executed. The medium may be any of various storage mediums readable by the computer 2a, or may be a communication line that is connected to the communication interface 2a3. The processing unit 2al may be a central processing unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### [Conventional Pulse Etching]

Conventionally, the source RF power and the bias RF power are pulsed, and the powers are synchronized and periodically turned ON and OFF in a repeated manner to etch an etching target film. Alternatively, a sequence of voltage pulses of the source RF power and the first DC signal is executed, and the powers and voltages are synchronized and periodically turned ON and OFF in a repeated manner to etch an etching target film.

In the next-generation etching target film structure, a pitch between concave portions such as trenches and holes formed in the etching target film under a mask decreases, and a CD size of the concave portion is reduced. Therefore, when etching the next-generation etching target film structure, it is important to improve a selectivity ratio of a mask by depositing deposits caused by reactive active species (radicals) on an upper portion of the mask without damaging opening characteristics of a bottom of the concave portion in the etching target film.

Therefore, in the embodiment, a plasma processing apparatus capable of improving a selectivity ratio of a mask is proposed.

As an example of a film structure on a substrate processed by an aspect of the present disclosure, the substrate W includes an etching target film and a mask on the etching target film. A concave portion having a hole shape or a line shape is formed in the mask, and the etching target film is etched in a shape of the concave portion. In one example, the etching target film is a silicon-containing film such as a silicon oxide film (SiO₂), and the mask is a boron silicon film, but the present disclosure is not limited thereto.

### [RF Power and DC Pulse Voltage]

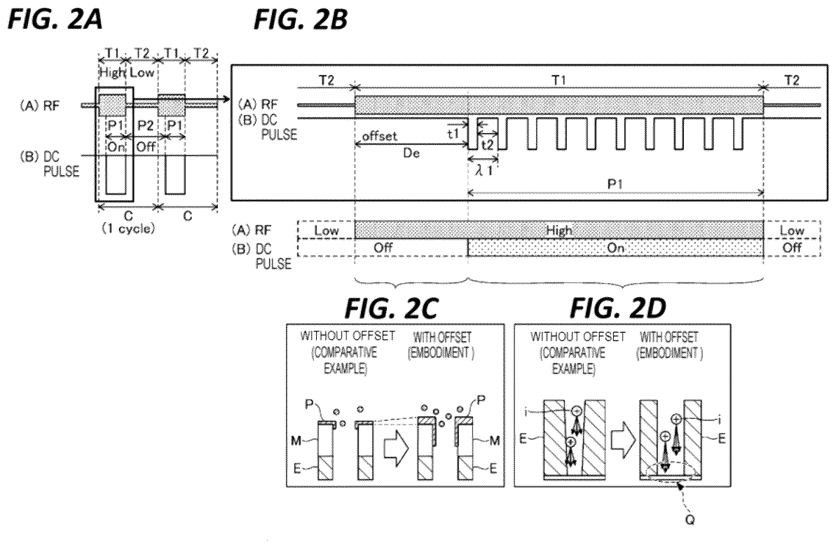

In the plasma processing apparatus according to the embodiment, a supply timing of (A) RF power and (B) DC pulse voltage will be described with reference to FIGS. 2A to 2D. FIGS. 2A to 2D are a time chart illustrating RF power and a DC pulse voltage according to the embodiment. FIG. 2B is an enlarged view of a frame in FIG. 2A. In the present disclosure, the RF power is the source RF power (source RF signal), but is not limited thereto, and may be bias RF power (bias RF signal). The DC pulse voltage is a voltage pulse of the first DC signal.

As illustrated in FIGS. 2A and 2B, in a process of etching an etching target film on the substrate W, the RF power illustrated in (A) is supplied, thereby etching the etching target film on the substrate W using a plasma generated from a processing gas. The RF power supply 31 periodically supplies RF power at levels of “High” and “Low” to the substrate support 11 (lower electrode), with a repetition period C illustrated in FIG. 2A as one cycle. However, the RF power may also be supplied to the shower head 13 (upper electrode). In the present disclosure, the RF power supply 31 (first RF generating unit 31a) is coupled to the lower electrode to supply the RF power as illustrated in (A).

The lower electrode may be a lower electrode (base 1110, see FIG. 1) that supports the substrate support 11, or may be an electrode 1112b (see FIG. 1) disposed within the substrate support 11. In one example, the substrate support 11 may be the electrostatic chuck 1111 (see FIG. 1).

In (A) in FIG. 2A, “High” (hereinafter, referred to as “high state” or “high”) is an example of indicating a first power level of the RF power. For example, the first power level is greater than 0 W. Meanwhile, in (A), “Low” (hereinafter, referred to as “low state” or “low”) is an example of indicating a second power level of RF power. The second power level of the RF power is less than the first power level and is equal to 0 W or greater than or 0 W.

A first period T1 (first sub-period) in which the RF power is in a high state and a second period T2 (second sub-period) in which the RF power is in a low state are repeated in this order. The first period T1 in which the RF power is in an ON-state and the second period T2 in which the RF power is in an OFF-state may be repeated in this order. The first period T1 has a duty ratio within a range of 10% to 60% of the repetition period C. The duty ratio refers to a ratio of the first period T1 and is the ratio of the first period T1 to the total time represented by (first period T1+second period T2). The repetition period C has a repetition frequency within a range of 0.1 kHz to 50 KHz.

In the supply of the DC pulse voltage in (B), a voltage of a pulse waveform having a negative polarity is periodically supplied. The term “periodicity” mentioned here has two meanings. One of the meanings is the periodicity of an ON-state in a period P1 in FIG. 2A and an OFF-state in a period P2 in FIG. 2A. The period P1 in the ON-state is the first period T1 excluding an offset period De illustrated in FIG. 2B. The period P2 in the OFF-state includes the offset period De and the second period T2. The other of the meanings is the periodicity of an ON and OFF of the pulse waveform having the negative polarity, as illustrated in FIG. 2B, in the first period T1 (period P1) excluding the offset period De.

The DC power supply 32 sets a period in which the RF power in (A) is in a high state as the first period T1, sets a period in which the RF power is in a low state as the second period T2, and sets the DC pulse voltage in an OFF-state during a period from the start of the first period T1 to the end of the offset period De. The offset period De is within a range of 2% to 7% of the repetition period C. The DC power supply 32 supplies a DC pulse voltage by maintaining the DC pulse voltage in an ON-state during the first period T1 after the offset period De has elapsed, that is, a period P1 (=T1-De), and maintains the DC pulse voltage in an OFF-state during the second period T2. In this manner, the period P1 for supplying a DC pulse voltage having a negative polarity and the period P2 (=De+T2) for stopping the supply of the DC pulse voltage having a negative polarity are repeated in this order.

In the period P1 in which the DC pulse voltage is in the ON-state, ON (negative value) and OFF (0 V) of the DC pulse voltage are periodically repeated. In the period P2, the DC pulse voltage is in the OFF-state. When the DC pulse voltage is in the ON-state, it indicates that the DC pulse voltage is supplied to the lower electrode. Meanwhile, when the DC pulse voltage is in the OFF-state, it indicates that the DC pulse voltage is not supplied to the lower electrode (the DC pulse voltage is 0 V). However, during the period P2, a DC pulse voltage having an absolute value smaller than that of the DC pulse voltage during the period P1 may be supplied.

In the period P1 in which the DC pulse voltage is supplied, when assuming that a pulse frequency, which is a reciprocal of the period [wavelength (λ1)] of ON and OFF of the DC pulse voltage supplied to the lower electrode, is set as a first frequency f1, the first frequency f1 of the DC pulse voltage may have a pulse frequency within a range of 100 kHz to 1 MHz.

In addition, in the period P1, the duty ratio of the DC pulse voltage of the first frequency f1 is set as a first duty ratio. The first duty ratio represents the ratio of the ON-time of the DC pulse voltage, and is the ratio of the ON-time to the total time of ON-time T1 and OFF-time T2 of the DC pulse voltage in the first period P1 (t1/(t1+t2)). The DC pulse voltage is not limited to a rectangular wave, but may also be a pulse waveform of a triangular wave, an impulse waveform, a trapezoidal wave, or a combination thereof.

In this manner, when the RF power and the DC pulse voltage are periodically controlled to be ON/OFF or high/low, in the embodiment, the RF power and the DC pulse voltage are not completely synchronized, and the DC pulse voltage is in the OFF-state for the offset period De from the start of the first period T1. That is, the DC pulse voltage is controlled from the OFF-state to the ON-state after waiting of the lapse of the offset period De, without changing the DC pulse voltage from the OFF-state to the ON-state simultaneously with changing the RF power from the low state to the high state in the first period T1. Then, the DC pulse voltage is in the ON-state during the first period T1 excluding the offset period De. Thereafter, in the second period T2, the RF power changes from the high state to the low state and at the same time, the DC pulse voltage changes from the ON-state to the OFF-state. By offsetting the DC pulse voltage by the offset period De, etching characteristics may be improved. The offset period De corresponds to a “delay period” until the DC pulse voltage becomes in an ON-state from the start of the first period T1.

Generally, when a selectivity ratio of a mask increases, mask remains (remaining film of the mask) with respect to an etching amount of the etching target film increases, and the selectivity ratio of the mask is improved. Meanwhile, due to a trade-off relationship, the opening characteristics of the bottom of the concave portion in the etching target film are degraded, so that it difficult to secure verticality at the bottom of the concave portion.

In the embodiment, the RF power is controlled from the low state to the high state with the start of the first period T1. In this regard, the DC pulse voltage maintains the OFF-state during the offset period De, and after the offset period De has elapsed, has a so-called “rear entrance section of the DC pulse voltage” in which the DC pulse voltage changes from the OFF-state to the ON-state. Accordingly, the selectivity ratio of the mask may be improved without damaging the opening characteristics of the bottom of the concave portion in the etching target film.

The reason for this will be explained with reference to FIGS. 2C and 2D. The “Comparative Example” illustrated in FIGS. 2C and 2D is a case where the “rear entrance section of the DC pulse voltage” does not exist (without offset). That is, the Comparative Example refers to a case where the RF power and the DC pulse voltage are synchronized and controlled to be high or low or to be ON or OFF. The “embodiment” illustrated in FIGS. 2C and 2D is a case where the “rear entrance section of the DC pulse voltage” exists (with offsets). That is, the “embodiment” is a case where the DC pulse voltage is controlled from the OFF-state to the ON-state by delaying the offset period De from the control of the RF power from the low state to the high state [see offset in FIG. 2B].

When the RF power is in a high state, since a higher level of power is supplied compared to a case where the RF power is in a low state, the electron density (Ne) of the plasma increases, so that etching of an etching target film E is promoted. As a result, when the RF power is in a high state, an increased amount of deposits P caused by reactive active species generated by the dissociation of the processing gas are deposited on a mask M, thereby functioning to protect the mask M. At this time, in the Comparative Example illustrated in FIG. 2C, since the “rear entrance section of the DC pulse voltage” does not exist, the DC pulse voltage is applied simultaneously with the RF power. When a DC pulse voltage having a negative polarity is applied, ions in the plasma are introduced into the substrate W on the substrate support 11, and the ions collide with the mask M, so that the amount of the deposits P on the mask M is reduced.

Meanwhile, in the embodiment illustrated in FIG. 2C, since the “rear entrance section of the DC pulse voltage” exists, the DC pulse voltage is not applied until the offset period De is terminated. Therefore, ions are not introduced into the substrate W until the offset period De is terminated, so that the amount of ions colliding with the mask M is low. Accordingly, the amount of the deposits P caused by reaction by-products deposited on the mask M does not decrease, and the mask M is protected. As a result, in the embodiment illustrated in FIG. 2C, the deposits P are deposited not only on an upper surface of the mask M but also on a side surface of the mask M, compared to the Comparative Example. Thus, a selectivity ratio of the mask is improved, and verticality of the mask M is also improved, so that verticality of a shape of the concave portion in the etching target film E is also improved.

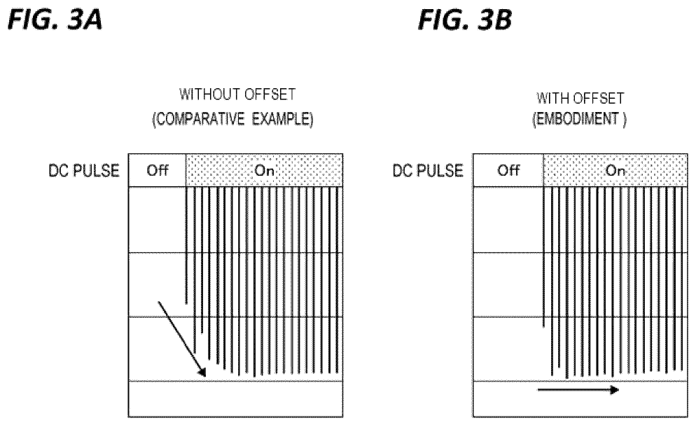

FIGS. 3A and 3B are diagrams illustrating an example of an increase in the DC pulse voltage having a negative polarity in the case of the “Comparative Example (without offset)” in FIG. 3A and the “Embodiment (with offset)” in FIG. 3B. In the cases of the “Comparative Example (without offset)” and the “Embodiment (with offset)”, waveforms of rises in the DC pulse voltage at an initial time are different. In the case of the Comparative Example in FIG. 3A, since the DC pulse voltage is applied simultaneously with the supply of the RF power, a variation in the load of the plasma caused by a change in the RF power from the low state to the high state is affected. Thus, as indicated by an arrow in FIG. 3A, a waveform of the DC pulse voltage is dispersed at an initial application time and is not a rectangular pulse waveform.

In this regard, in the embodiment in FIG. 3B, the RF power of a single frequency is supplied during the offset period De to increase the electron density (Ne) of the plasma. In addition, when the offset period De in which the electron density (Ne) is stable has elapsed, the DC pulse voltage changes from the OFF-state to the ON-state. As a result, when the DC pulse voltage is applied, the variation in the load of the plasma is low due to the stabilization of the electron density (Ne). Therefore, as indicated by an arrow in FIG. 3B, the DC pulse voltage rises early from an initial application time at which the DC pulse voltage changes from the OFF-state to the ON-state, and becomes a rectangular pulse waveform.

Therefore, in the embodiment, introduction of ions into the substrate W increases compared to the Comparative Example. In addition, the energy of the ions is uniform and is also risen. As a result, as illustrated in FIG. 2D, in the embodiment, the ions easily enter the bottom of the etching target film E from the time of the rise of the DC pulse voltage, compared to the Comparative Example, thereby improving etching efficiency, and improving the opening characteristics of the bottom of the etching target film E (see Q in FIG. 2D), so that the verticality of the sidewall of the concave portion may be improved.

By these factors, the controllability of the deposits P may be improved (FIG. 2C), and the etching efficiency of the etching target film E may be improved (FIG. 2D). As a result, the selectivity ratio of the mask M may be improved without damaging the opening characteristics of the bottom of the concave portion in the etching target film E.

### [Appropriate Range of Delay Period]

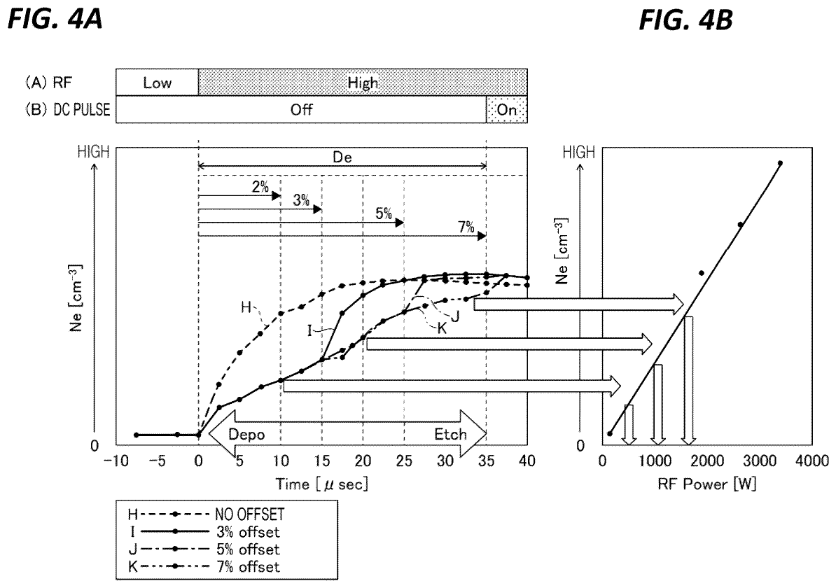

The appropriate range of the offset period De will be described with reference to FIGS. 4A and 4B. FIGS. 4A and 4B are graphs illustrating an example of the relationship between the offset period De and the electron density (Ne) and RF power according to the embodiment.

A horizontal axis in FIG. 4A refers to time (usec), and “0” on the horizontal axis refers to a start time of the first period T1 and the offset period De. A vertical axis in FIG. 4A refers to electron density (Ne) (cm⁻³) of the plasma. A horizontal axis in FIG. 4B refers to RF power W, and a vertical axis in FIG. 4B refers to electron density (Ne) (cm⁻³) of the plasma.

In an experiment that is conducted to obtain an appropriate range of the offset period De, the offset period De was variably controlled at a ratio of 0%, 3%, 5%, and 7%, and both the RF power in (A) and the DC pulse voltage in (B) were supplied to the substrate support 11 (lower electrode). An evaluation result of the relationship between the offset period De and the electron density (Ne) at this time is illustrated in FIG. 4A. In addition, an evaluation result of the relationship between the RF power and the electron density (Ne) at this time is illustrated in FIG. 4B.

A line H in FIG. 4A illustrates a change in electron density distribution over time when “no offset period De exists (the offset period De is 0%)”, that is, when the RF power is controlled to be high and at the same time, the DC pulse voltage is controlled to be in the ON-state in the first period T1. In the line H, electron density (Ne) increased rapidly from 0 μsec.

A line I in FIG. 4A illustrates a change in electron density distribution over time when the “offset period De is 3%”, that is, when a delay period until the DC pulse voltage is turned to be ON for the first period T1 is 3% of the repetition period C. In the line I, the electron density (Ne) from 0 μsec to 15 μsec increased more gradually than the electron density (Ne) of the line H. The electron density (Ne) of the line I increased rapidly after 15 μsec.

A line J in FIG. 4A illustrates a change in electron density distribution over time when the “offset period De is 5%”, that is, when the delay period until the DC pulse voltage is turned ON for the first period T1 is 5% of the repetition period C. In the line J, the electron density (Ne) from 0 μsec to 15 μsec increased more gradually than the electron density (Ne) of the line H, similarly to the line I. The electron density (Ne) of the line J increased gradually even after 15 μsec and increased slightly rapidly after 25 usec.

A line K in FIG. 4A illustrates a change in electron density distribution over time when the “offset period De is 7%”, that is, when the delay period until the DC pulse voltage is turned ON for the first period T1 is 7% of the repetition period C. The electron density (Ne) on the line K became a change in electron density, which is approximately the same as the electron density (Ne) on the line J. However, an increase in the electron density distribution on the line K was the most gradual.

A vertical axis in FIG. 4B corresponds to the electron density (Ne) represented on the vertical axis in FIG. 4A, and a horizontal axis in FIG. 4B represents RF power W supplied to generate the electron density (Ne) on the vertical axis. For example, the RF power assumed from the line I to the line K of each electron density at the time of the lapse of the offset period De when the offset period De is within a range of 3% to 7% is within a range of about 1000 W to about 2000 W. From this graph, the RF power assumed from each electron density at the time of the lapse of the offset period De when the offset period De is within a range of 2% to 7% is within a range of about 500 W to about 2000 W. That is, when the RF power in (A) in FIG. 4A is supplied within a range of about 500 W to about 2000 W and the offset period De is within the range of 2% to 7%, the collision of ions may be reduced to increase the amount of deposits on the mask M, so that the selectivity ratio of the mask may be improved. In addition, when the RF power in (A) in FIG. 4A is supplied within a range of about 1000 W to about 1500 W and the offset period De is in the range of 3% to 5%, the collision of ions may be further reduced to further increase the amount of deposits on the mask M, so that the selectivity ratio of the mask may be improved.

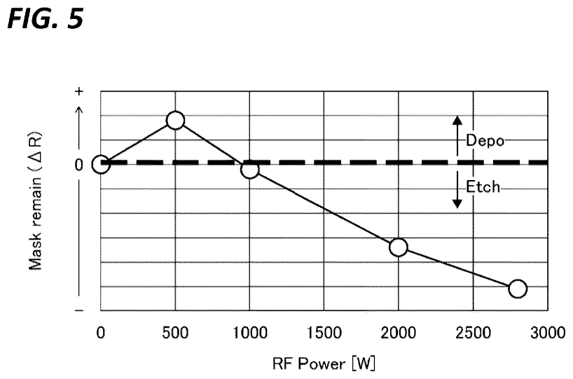

FIG. 5 is a diagram illustrating an experimental result of RF power and mask remains (film remaining on the mask M) according to an embodiment. A horizontal axis represents RF power W, and a vertical axis represents a difference (ΔR) in the mask remains. The mask remains (ΔR) on the vertical axis are represented by the difference (ΔR) with an initial value of a height of the mask M when assuming that the initial value of the height of the mask M is 0. For example, when the difference (ΔR) is positive (+) with respect to “0” of the vertical axis, it indicates that an amount of the remaining film on the mask M is greater than that of an initial state. When the difference (ΔR) is negative (−), it indicates that an amount of the remaining film on the mask M is less than that of the initial state. When the difference (ΔR) in the mask remains increases in a positive (+) direction, it indicates that the amount of deposits on the mask M increases, so that the mask M is protected by the deposits and the selectivity ratio of the mask is large. In addition, when the difference (ΔR) in the mask remains increases in a negative (−) direction, it indicates that the mask M is worn away by the collision of ions, and the mask M is not protected by the deposits, so that the selectivity ratio of the mask is small.

According to the result of FIG. 5, when the RF power is 2000 W or more, the mask M is etched due to the collision of ions, and the selectivity ratio of the mask may not be improved. Therefore, by supplying the RF power in the range of about 500 W to about 2000 W and setting the offset period De within the range of 2% to 7%, deposits due to reactive active species are deposited on the mask M, and the selectivity ratio of the mask may be improved.

The reason why the mask remains decrease to a minus when RF power of 2000 W or more is supplied will be explained. A fluorine (F)-containing gas is mainly used as a processing gas for an etching target film. The fluorine-containing gas may include, for example, at least one of C₄F₆, C₄F₈, C₃F₆, NF₃, WF₆, and C₃F₈. Further, an oxygen-containing gas and/or an inert gas may be added to the fluorine-containing gas.

When RF power of 2000 W or more is supplied, dissociation of the processing gas progresses, and a highly dissociated gas is formed. As a result, the amount of highly dissociated fluorine compounds in substances included in the reactive active species generated by dissociation of the processing gas increases, and the mask is worn away by the fluorine compounds.

From the above, by supplying RF power of about 500 W to about 2000 W, it is possible to suppress dissociation of the processing gas. Further, when the offset period De is within the range of 2% to 7% of the repetition period C, the selectivity ratio of the mask may be improved. When the offset period De is within the range of 2% to 7% of the repetition period C, referring to FIGS. 4A and 4B, the offset period is within a range of 10 μsec to 35 μsec. That is, by setting the offset period De within the range of 10 μsec to 35 μsec, the selectivity ratio of the mask may be improved.

When the offset period De is greater than 7% of the repetition period, the opening characteristics of the bottom of the concave portion formed in the etching target film are degraded, so that etching efficiency and verticality of an etching shape are lowered. This is because, as the offset period De increases, the ON-time of the DC pulse voltage is shortened, and the total ion induction energy in the repetition period C decreases, which leads to a decrease in etching rate. Therefore, when the offset period De is greater than 7% of the repetition period C, the deposits on the mask M increase and the selectivity ratio of the mask is improved, but the etching efficiency and the opening characteristics of the bottom of the concave portion are degraded, so that a well-balanced effect of the both aspects may not be obtained.

Meanwhile, when the offset period De is shorter than 2% of the repetition period, the deposition effect of reactive active species due to the single frequency of the RF power is not obtained. Therefore, when the offset period De is shorter than 2% of the repetition period C, the total ion induction energy in the repetition period C increases to improve the etching rate, but the deposits on the mask M decrease. As a result, the selectivity ratio of the mask decreases, so that a well-balanced effect of the both aspects may not be obtained. Therefore, to obtain the effects of both improving the selectivity ratio of the mask by the deposits on the mask M and improving the etching rate by increasing the total ion energy, the offset period De is set within the range of 2% to 7% of the repetition period C. As a result, the selectivity ratio of the mask may be improved by depositing deposits caused by reactive active species on an upper portion of the mask without damaging the opening characteristics of the bottom of the concave portion in the etching target film.

In addition, the offset period De may be preferably set within a range of 3% to 5% of the repetition period C. When the offset period is within the range of 3% to 5%, referring to FIGS. 4A and 4B, the offset period is within a range of 15 μsec to 25 μsec. That is, by setting the offset period De within the range of 15 μsec to 25 μsec, a sufficient deposition effect of reactive active species on the mask M is obtained, and an effect of increasing the etching efficiency and the verticality of the etching shape is obtained. As a result, the selectivity ratio of the mask may be further improved without damaging the opening characteristics of the bottom of the concave portion in the etching target film.

### [Variation 1]

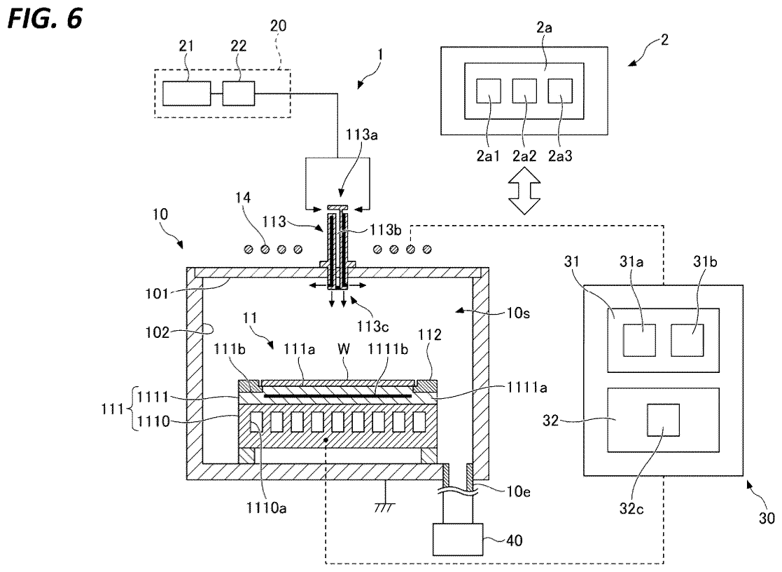

A plasma processing apparatus according to the present disclosure is not limited to the capacitively-coupled plasma processing apparatus 1 illustrated in FIG. 1, but may also be applied to an inductively coupled plasma processing apparatus illustrated in FIG. 6. The plasma processing system includes an inductively coupled plasma processing apparatus 1 and a control unit 2. The inductively coupled plasma processing apparatus 1 includes a plasma processing chamber 10, a gas supply unit 20, a power supply 30, and an exhaust system 40. The plasma processing chamber 10 includes a dielectric window 101. The plasma processing apparatus 1 includes a substrate support 11, a gas introduction unit, and an antenna 14. The substrate support 11 is disposed within the plasma processing chamber 10. The antenna 14 is disposed on or above the plasma processing chamber 10 (i.e., on or above the dielectric window 101). The plasma processing chamber 10 includes a plasma processing space 10s defined by the dielectric window 101, sidewalls 102 of the plasma processing chamber 10, and the substrate support 11. The plasma processing chamber 10 includes at least one gas supply inlet for supplying at least one processing gas to the plasma processing space 10s and at least one gas outlet for discharging the gas from the plasma processing space. The plasma processing chamber 10 is grounded.

The gas introduction unit is configured to introduce at least one processing gas from the gas supply unit 20 into the plasma processing space 10s. In the embodiment, the gas introduction unit includes a center gas injector (CGI) 113. The center gas injector 113 is disposed above the substrate support 11 and is attached to a center opening formed in the dielectric window 101. The center gas injector 113 includes at least one gas supply inlet 113a, at least one gas path 113b, and at least one gas introduction inlet 113c. A processing gas supplied to the gas supply inlet 113a is introduced into the plasma processing space 10s from the gas introduction inlet 113c through the gas path 113b. The gas introduction unit may include one or more side gas injectors (SGI) attached to one or more openings formed in the sidewall 102 in addition to or instead of the center gas injector 113.

The power supply 30 includes an RF power supply 31 coupled to the plasma processing chamber 10 through at least one impedance matching circuit. The RF power supply 31 is configured to supply at least one RF signal (RF power) to at least one bias electrode and the antenna 14. Accordingly, a plasma is formed from at least one processing gas supplied to the plasma processing space 10s. Therefore, the RF power supply 31 may function as at least a portion of a plasma generating unit configured to generate a plasma from one or more processing gases in the plasma processing chamber 10. By supplying a bias RF signal to the at least one lower electrode, a bias potential is generated at the substrate W, so that ion components in the formed plasma may be introduced to the substrate W.

In the embodiment, the RF power supply 31 includes a first RF generating unit 31a and a second RF generating unit 31b. The first RF generating unit 31a is coupled to the antenna 14 and configured to generate a source RF signal (source RF power) for plasma generation through at least one impedance matching circuit. In the embodiment, the source RF signal has a frequency within a range of 10 MHz to 150 MHz. In the embodiment, the first RF generating unit 31a may be configured to generate a plurality of source RF signals having different frequencies. The generated one or more source RF signals are supplied to the antenna 14.

The second RF generating unit 31b is coupled to at least one bias electrode through at least one impedance matching circuit and configured to generate a bias RF signal (bias RF power). A frequency of the bias RF signal may be the same as or different from the frequency of the source RF signal. In the embodiment, the bias RF signal has a frequency lower than the frequency of the source RF signal. In the embodiment, the bias RF signal has a frequency within a range of 100 kHz to 60 MHz. In the embodiment, the second RF generating unit 31b may be configured to generate a plurality of bias RF signals having different frequencies. The generated one or more bias RF signals are supplied to at least one bias electrode. In various embodiments, at least one of the source RF signal and the bias RF signal may be pulsed.

The power supply 30 may include a DC power supply 32 coupled to the plasma processing chamber 10. The DC power supply 32 includes a bias DC generating unit 32c. In the embodiment, the bias DC generating unit 32c is connected to at least one bias electrode and is configured to generate a bias DC signal. The generated bias DC signal is applied to at least one bias electrode.

In various embodiments, the bias DC signal may be pulsed. In this case, a sequence of voltage pulses is applied to at least one bias electrode. The voltage pulses may have a pulse waveform of a rectangular wave, a trapezoidal wave, a triangular wave, an impulse waveform, or a combination thereof. In the embodiment, a waveform generating unit for generating a sequence of voltage pulses from a DC signal is connected between the bias DC generating unit 32c and the at least one bias electrode. Therefore, the bias DC generating unit 32c and the waveform generating unit constitute a voltage pulse generating unit. The voltage pulses may have a positive polarity or a negative polarity. In addition, the sequence of the voltage pulses may include one or more voltage pulses having a positive polarity and one or more voltage pulses having a negative polarity within one cycle. The bias DC generating unit 32c may be installed in addition to the RF power supply 31, or may be installed instead of the second RF generating unit 31b.

The antenna 14 includes one or more coils. In the embodiment, the antenna 14 may include an outer coil and an inner coil disposed coaxially. In this case, the RF power supply 31 may be connected to both the outer coil and the inner coil, or may be connected to one of the outer coil and the inner coil. In the former case, the same RF generating unit may be connected to both the outer coil and the inner coil, or separate RF generating units may be separately connected to the outer coil and the inner coil.

Since the substrate support 11, the ring assembly 112, the exhaust system 40, and the control unit 2 have the same configurations as those of the capacitively-coupled plasma processing apparatus 1 of FIG. 1, descriptions thereof are omitted.

In the plasma processing apparatus 1 of FIG. 6, the RF power supply 31 is coupled to the plasma processing chamber 10 and generates an RF signal that periodically supplies RF power for each repetition period C. The DC power supply 32 is coupled to the bias electrode and generates a DC signal that periodically supplies a DC pulse voltage.

The RF power supply 31 supplies RF power by maintaining the RF signal to a first power level during the first period T1 in the repetition period C. The RF power supply 31 supplies RF power by maintaining the RF signal to a second power level lower than the first power level during the second period T2 in the repetition period C.

The DC power supply 32 supplies a DC pulse voltage by maintaining the DC signal in an OFF-state in the offset period De from the start of the first period T1 and maintaining the DC signal in an ON-state in the first period T1 after the offset period De has elapsed, and maintains the DC signal in an OFF-state. The offset period De is within the range of 2% to 7% of the repetition period C. The offset period De is preferably within the range of 3% to 5% of the repetition period C.

According to this, the RF power is controlled from the low state to the high state at the start of the first period T1. The offset period De maintains the DC pulse voltage in the OFF-state. After the offset period De has elapsed, there exists a so-called “rear entrance section of the DC pulse voltage” in which the DC pulse voltage changes from the OFF-state to the ON-state. As a result, the selectivity ratio of the mask may be improved without damaging the opening characteristics of the bottom of the concave portion in the etching target film.

Also, the RF power supply 31 may be coupled to the bias electrode.

### [Variation 2]

A plasma processing apparatus according to the present disclosure may supply a bias RF signal (bias RF power) in a pulse form to the lower electrode, instead of the DC pulse voltage, in the capacitively-coupled plasma processing apparatus 1 illustrated in FIG. 1.

For example, the first RF power supply (first RF generating unit 31a) of the RF power supply 31 is coupled to the plasma processing chamber 10 and generates a first RF signal that periodically supplies RF power for each repetition period C. The second RF power supply (second RF generating unit 31b) of the RF power supply 31 is coupled to the substrate support 11 (lower electrode) and generates a second RF signal that periodically supplies pulsed bias RF power.

The first RF power supply supplies RF power by maintaining the first RF signal to a first power level during a first period T1 in the repetition period C and maintaining the first RF signal to a second power level lower than the first power level during a second period T2 in the repetition period C.

The second RF power supply supplies pulsed bias RF power by maintaining the second RF signal in an OFF-state during the offset period D from the start of the first period T1 and maintaining the second RF signal to a third power level during the first period T1 after the offset period De has elapsed, and maintains the second RF signal in an OFF-state during the second period T2. The offset period De is within a range of 2% to 7% of the repetition period C. The offset period De may be preferably within a range of 3% to 5% of the repetition period C.

According to this, the RF power is controlled to change from the low state to the high state with the start of the first period T1. In this regard, the pulsed bias RF power maintains an OFF-state during the offset period De, and after the offset period De has elapsed, has a so-called “rear-entrance section for the pulsed bias RF power” in which the DC pulse voltage changes from the OFF-state to an ON-state. Accordingly, the selectivity ratio of the mask may be improved without damaging the opening characteristics of the bottom of the concave portion in the etching target film.

The first RF power supply may be coupled to the substrate support 11 (lower electrode).

### [Other Variations]

Other variations are described.

A level of the DC pulse voltage (amplitude of the DC pulse voltage) having a negative polarity may be within a range of −5 kV to −30 kV. However, the DC pulse voltage is not limited to a negative pulse voltage, and may be a positive pulse voltage. For example, an amplitude of the DC pulse voltage having a positive polarity may be within a range of 0.5 kV to 20 kV.

As described above, the plasma processing apparatus according to the embodiments of the present disclosure may improve the selectivity ratio of the mask.

The plasma processing apparatus according to the embodiment disclosed herein should be considered as an example and not restrictive in all respects. The above embodiment may be modified and enhanced in various forms without departing from the claims and spirit thereof. Matters described in the above embodiment may take other configurations to the extent not inconsistent, and may be combined to the extent not inconsistent.

The embodiment disclosed above includes, for example, the following aspects.

(Appendix 1) A plasma processing apparatus including: a plasma processing chamber, a substrate support disposed within the plasma processing chamber and including a lower electrode; an upper electrode disposed above the substrate support; an RF power supply configured to supply an RF signal to the upper electrode or the lower electrode, the RF signal having a first power level during a first sub-period in a repetition period and a second power level during a second sub-period in the repetition period; and a DC power supply configured to supply a DC signal to the lower electrode, the DC signal having an OFF-state during a delay period in the first sub-period, having a sequence of a plurality of DC pulses during the first sub-period excluding the delay period, and having an OFF-state during the second sub-period, the delay period being within a range of 2% to 7% of the repetition period.

(Appendix 2) The plasma processing apparatus described in Appendix 1, in which the delay period is within a range of 10 μsec to 35 μsec.

(Appendix 3) The plasma processing apparatus described in Appendix 1, in which the delay period is within a range of 3% to 5% of the repetition period.

(Appendix 4) The plasma processing apparatus described in Appendix 2 or 3, in which the delay period is within a range of 15 μsec to 25 μsec.

(Appendix 5) The plasma processing apparatus described in any one of Appendices 1 to 4, in which the first period has a duty ratio within a range of 10% to 60% with respect to the repetition period.

(Appendix 6) The plasma processing apparatus described in any one of Appendices 1 to 5, in which the repetition period has a repetition frequency within a range of 0.1 kHz to 50 kHz.

(Appendix 7) The plasma processing apparatus described in Appendix 6, in which the sequence of the plurality of DC pulses has a pulse frequency within a range of 100 kHz to 1 MHz.

(Appendix 8) The plasma processing apparatus described in any one of Appendices 1 to 7, wherein the second power level is greater than 0 W.

(Appendix 9) The plasma processing apparatus described in Appendix 8, in which each of the plurality of DC pulses has a voltage level within a range of −5 kV to −30 kV.

(Appendix 10) A plasma processing apparatus including: a plasma processing chamber; a substrate support disposed within the plasma processing chamber and including an electrode; an RF power supply coupled to the plasma processing chamber and configured to generate an RF signal, the RF signal having a first power level during a first sub-period in a repetition period and a second power level during a second sub-period in the repetition period; and a DC power supply coupled to the electrode and configured to generate a DC signal, the DC signal having an OFF-state during a delay period in the first sub-period, having a sequence of a plurality of DC pulses during the first sub-period excluding the delay period, and having an OFF-state during the second sub-period, the delay period being within a range of 2% to 7% of the repetition period.

(Appendix 11) A plasma processing apparatus including: a plasma processing chamber; a substrate support disposed within the plasma processing chamber and including an electrode; a first RF power supply coupled to the plasma processing chamber and configured to generate a first RF signal, the first RF signal having a first power level during a first sub-period in a repetition period and a second power level during a second sub-period in the repetition period; and a second RF power supply coupled to the electrode and configured to generate a second RF signal, the second RF signal having an OFF-state during a delay period in the first sub-period, having a third power level during the first sub-period excluding the delay period, and having an OFF-state during the second sub-period, the delay period being within a range of 2% to 7% of the repetition period.

According to an aspect of the present disclosure, a selectivity ratio of a mask may be improved.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a plasma processing chamber;
a substrate support disposed within the plasma processing chamber and including a lower electrode;
an upper electrode disposed above the substrate support;
a radio-frequency (RF) power supply configured to supply an RF signal to the upper electrode or the lower electrode, the RF signal having a first power level during a first sub-period in a repetition period and a second power level during a second sub-period in the repetition period; and
a direct current (DC) power supply configured to supply a DC signal to the lower electrode, the DC signal having an OFF-state during a delay period in the first sub-period, having a sequence of a plurality of DC pulses during the first sub-period excluding the delay period, and having an OFF-state during the second sub-period, the delay period being within a range of 2% to 7% of the repetition period.

2. The plasma processing apparatus according to claim 1, wherein the delay period is within a range of 10 μsec to 35 μsec.

3. The plasma processing apparatus according to claim 1, wherein the delay period is within a range of 3% to 5% of the repetition period.

4. The plasma processing apparatus according to claim 2, wherein the delay period is within a range of 15 μsec to 25 μsec.

5. The plasma processing apparatus according to claim 1, wherein the first sub-period has a duty ratio within a range of 10% to 60% of the repetition period.

6. The plasma processing apparatus according to claim 1, wherein the repetition period has a repetition frequency within a range of 0.1 kHz to 50 KHz.

7. The plasma processing apparatus according to claim 6, wherein the sequence of the plurality of DC pulses has a pulse frequency within a range of 100 kHz to 1 MHz.

8. The plasma processing apparatus according to claim 1, wherein the second power level is greater than 0 W.

9. The plasma processing apparatus according to claim 8, wherein each of the plurality of DC pulses has a voltage level within a range of −5 kV to −30 kV.

10. A plasma processing apparatus comprising:
a plasma processing chamber;
a substrate support disposed within the plasma processing chamber and including an electrode;
an RF power supply coupled to the plasma processing chamber and configured to generate an RF signal, the RF signal having a first power level during a first sub-period in a repetition period and a second power level during a second sub-period in the repetition period; and
a DC power supply coupled to the electrode and configured to generate a DC signal, the DC signal having an OFF-state during a delay period in the first sub-period, having a sequence of a plurality of DC pulses during the first sub-period excluding the delay period, and having an OFF-state during the second sub-period, the delay period being within a range of 2% to 7% of the repetition period.

11. A plasma processing apparatus comprising:
a plasma processing chamber;
a substrate support disposed within the plasma processing chamber and including an electrode;
a first RF power supply coupled to the plasma processing chamber and configured to generate a first RF signal, the first RF signal having a first power level during a first sub-period in a repetition period and a second power level during a second sub-period in the repetition period; and
a second RF power supply coupled to the electrode and configured to generate a second RF signal, the second RF signal having an OFF-state during a delay period in the first sub-period, having a third power level during the first sub-period excluding the delay period, and having an OFF-state during the second sub-period, the delay period being within a range of 2% to 7% of the repetition period.
